(19) United States
(12) Patent Application Publication
(10) Pub. No.: US 2009/0080150 A1
(43) Pub. Date: Mar. 26, 2009

(54) Heat dissipation device for portable computer

(76) Inventors: Che Hua Chang, Sindian City (TW); Ting Hui Huang, Taoyuan City (TW); Chih Cheng Hsu, Jhongli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/003,519

(22) Filed: Dec. 28, 2007

(30) Foreign Application Priority Data
Sep. 25, 2007 (CN) 200720175678.9

(51) Int. Cl. H05K 7/20; G06F 1/20

(52) U.S. Cl. 361/679.49

(57) ABSTRACT

This invention relates to a heat dissipation device for portable computer. The heat dissipation device comprises: a housing including at least one fan casing and at least one duct, said fan casing having an air suction opening which communicates with said duct, at least one air outlet communicating with said fan casing being provided at the front end of said housing, at least one air inlet communicating with said fan casing being provided at the rear end of said housing; and at least one side-blow fan provided within the fan casing, the air suction face of the side-blow fan being opposite to the air suction opening, the air introducing from the air inlet into the duct passes being sucked by the side-blow fan into the fan casing after passing through the air suction opening and blowing out through the air outlet. In this manner, excellent heat dissipation effect collocating with the use of a portable computer can be obtained. In addition, noise generation is effectively prevented. Therefore, the effectiveness in practical application and the product quality can be further enhanced positively.

### BACKGROUND OF THE INVENTION

1. Field of the Invention

This invention relates to a heat dissipation device, particularly to a heat dissipation device for portable computer, which can produce better heat dissipation effect for the portable computer by cooperating with the use of a pad for the portable computer.

2. Brief Description of the Prior Art

Now a day, portable computer (notebook PC) has been becoming the main stream of the application of computer. However, in view of the inherent mechanism space limitation of the portable computer and the mode of use, heat dissipation effect is worse than that of the desk top computer. Thus, how to solve the heat dissipation for the portable computer is becoming more and more important. As everybody knows, bad heat dissipation of a computer may cause sluggish in use, even cause breakdown (crash) of a computer, moreover may cause accelerated aging of components such that the service lifetime is seriously shortened. Therefore, such products as heat dissipation device, heat dissipation pad or the like cooperating with the use of portable computer are disclosed, for example, in the associated patent publication No. M297495 in which a fan is provided in the base of the heat dissipater and an air outlet is provided at the front side, an air inlet being provided at a location corresponding to the upper cover. In this manner, the air outside the heat dissipater enters from the air inlet on the top surface of the upper cover by the suction action of the fan, then blows out from the air outlet at the front side of the heat sink so that heat dissipation effect can be obtained.

While this prior art has heat dissipation effect for the portable computer, a lot of defects has been found, For example, when the portable computer is disposed on the heat dissipater to operate, the air inlet on the top surface of the upper cover will be partially or completely blocked by the portable computer such that the entering of the cold air outside the heat dissipater will be blocked. Inasmuch as the base of the portable computer is the critical portion for heat dissipation, the blocking of the cold air outside the heat dissipater will cause bad heat dissipation effect induced by the air quantity blowing out from the air outlet corresponding to the base of the portable computer. Furthermore, due to the blocking of the air inlet of the heat dissipater, turbulent flow is easily induced in the air at the vicinity of the air inlet; moreover noise is apt to produce which often make user feel unpleasant. In addition, the air inlet of the upper housing of this prior art is disposed on the top surface of the upper cover, foreign material or liquid falls into the fan area within the heat dissipater such that interfering or shattering sound is easily generated during the fan operation, even the fan is easily damaged. Therefore, this design is not ideal and improvement is thus highly expected.

In view of the above fact, the inventor of this invention thus proposes a new heat dissipation device for portable computer having better practicality and effectiveness according to the improvement and solution made with respect to the defects in both the application and the structure of the existing structure, so as to give service to the society and upgrade the technology in this respect. Therefore, a total solution on the defects of the existing structure can certainly be anticipated.

### SUMMARY OF THE INVENTION

The object of this invention is to provide a heat dissipation device for portable computer which can produce better heat dissipation effect for the portable computer by collocating with the use of portable computer.

In order to achieve the above object, the heat dissipation device for portable computer of the present invention comprises: a housing including at least one fan casing and duct in the interior, said fan casing having an air suction opening which communicates with said duct, at least one air outlet communicating with said fan casing being provided at the front end of said housing, at least one air inlet communicating with said fan casing being provided at the rear end of said housing; and at least one side-blow fan provided within the fan casing, the air suction face of the side-blow fan being opposite to the air suction opening so that the air introducing from the air inlet into the duct being sucked by the side-blow fan into the fan casing after passing through the air suction opening and blowing out forward through the air outlet.

The advantages of the present invention are rapidity in air-blowing, uniformity and sufficiency in air supply quantity, and excellence in heat dissipation effectiveness.

The technical content, objects and effectiveness of the present invention will become more apparent by the detailed description of the following preferred embodiments of the present invention with reference to the accompanied drawings.

### BRIEF DESCRIPTION OF THE ACCOMPANYING DRAWINGS

The present invention will be better understood by the detailed description of the preferred embodiment with reference to the accompanying drawings, in which:

FIG. 1 is a perspective schematic front view of the present invention.

FIG. 2 is a perspective schematic rear view of the present invention.

FIG. 3 is a perspective schematic view of the lower housing of the present invention.

FIG. 4 is a side sectional schematic view of the lower housing of the present invention.

FIG. 5 is a perspective schematic view of the upper housing of the present invention.

FIG. 6 is a schematic view of the position of the side-blow fan of the present invention.

FIG. 7 is a side sectional schematic view of the present invention.

FIG. 8 is a schematic view showing a modified embodiment of the lower housing of the present invention.

FIG. 9 is a schematic view showing the application of the modified embodiment of the lower housing of the present invention.

### DETAILED DESCRIPTION OF THE PREFERRED EMBODIMENTS

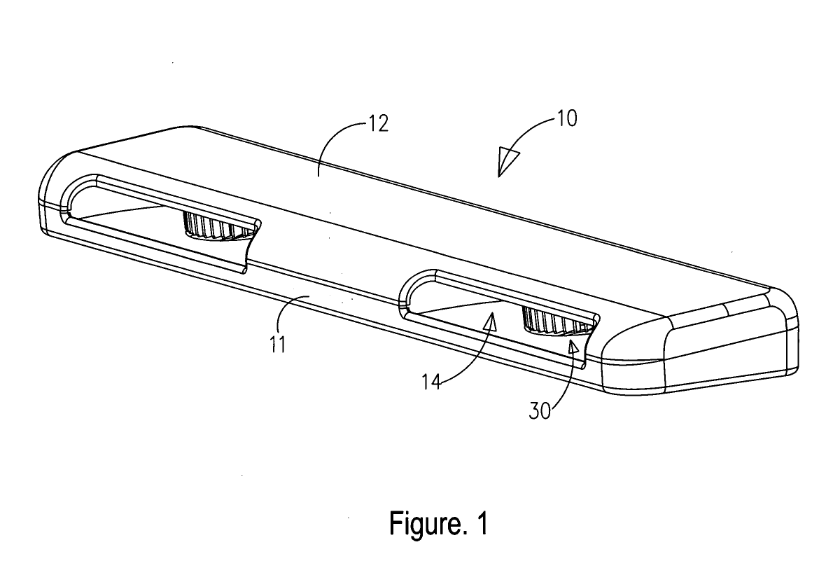

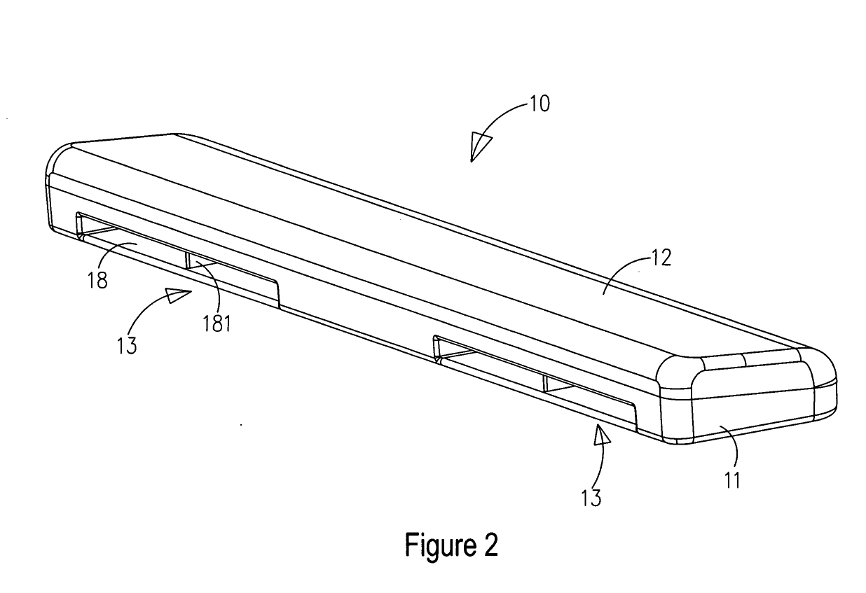

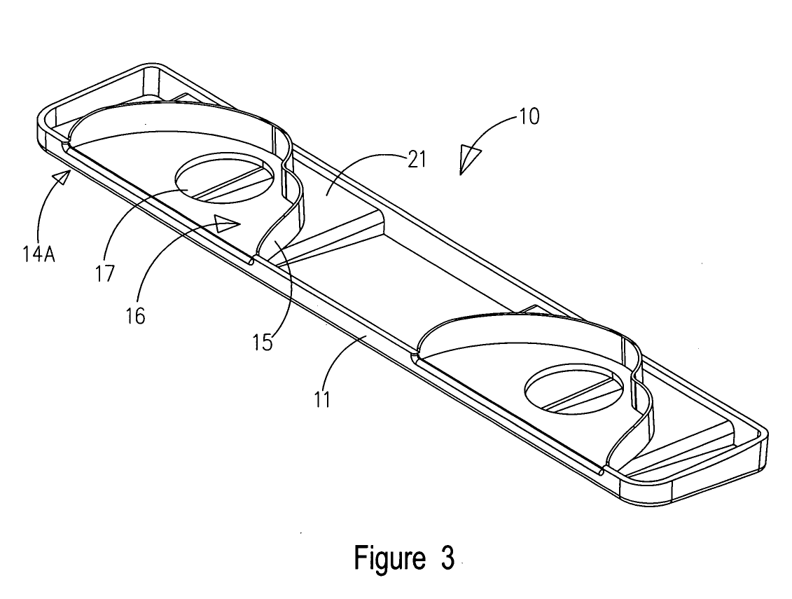

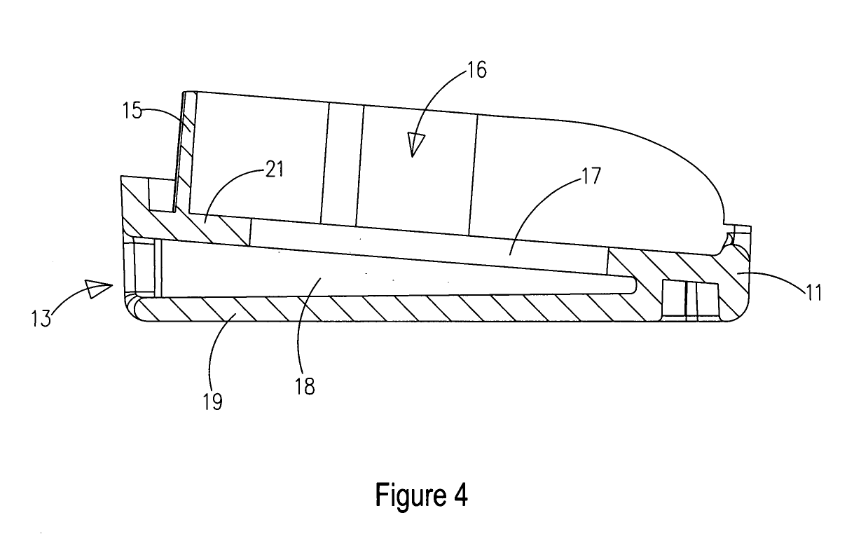

Referring to FIGS. 1 and 2, the heat dissipation device for portable computer of the present invention comprises a housing 10 and a side-blow fan 30. The housing 10 is formed by a lower housing 11 and an upper housing 12. Air inlets 13 are provided at both sides of the rear end and air outlets 14 are provided at both sides of the front end of the housing 10. Referring to FIG. 3, half-surrounding wind enclosing walls 15 are provided at both sides in the interior of the lower housing 11. An air outlet slot opening 14A is provided at the front end of each wind enclosing wall 15. The wind enclosing wall 15 is used to form a fan casing 16 which has a bore shape air suction opening 17. Referring to FIG. 4, air ducts 18 are provided at both sides of the bottom of the lower housing 11, which are formed by the bottom wall 19 and the inner wall 21 of the housing. The rear end of each air duct 18 is connected with the air inlet 13. The front end of each air duct 18 is a closed end 22, and each air duct 18 communicates with the fan casing 16 through the air suction opening 17. Additionally, a support partitioning plate 181 is further provided within each air duct 18, which not only supports the inner wall 21 of the housing but also provides better flow-dividing and guiding for the air inside the air duct 18. In the preferred embodiment, the inner wall 21 of the housing is arranged as inclined shape such that the air duct 18 forms a channel tapering from the rear end to the front end. In this manner, the air speed in the air duct 18 is gradually increased. Besides, the inclined arrangement of the inner wall 21 of the housing provides a reference that facilitates the use of a pad for portable computer and increases the leaning operational stability of a portable computer.

The above housing 10 has a power supply/signal transmission port (not shown) which is electrically connected to a side-blow fan 30, and the power supply/signal transmission port can be connected to power source, portable computer or another electronic device by lead wire so as to provide connection and transmission for the power supply or signal. Certainly, the power supply; for the side-blow fan can also be a dry battery type.

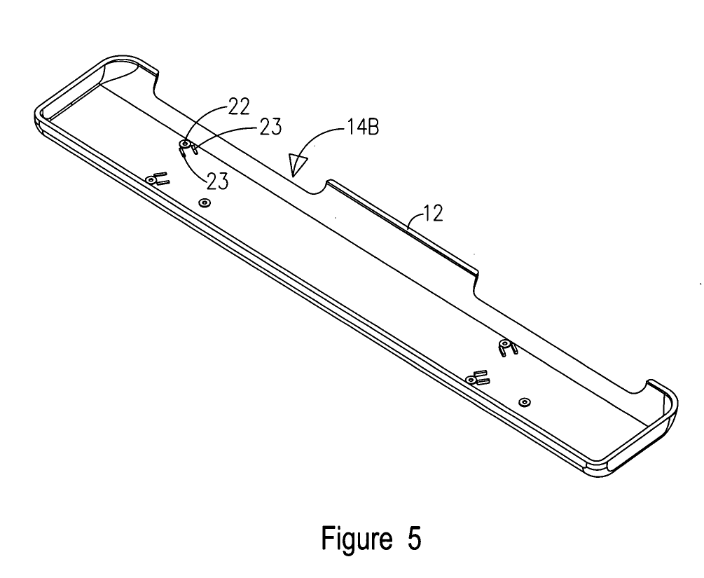

Referring to FIG. 5, the upper housing 12 is assembled on the lower housing 11 by wedging connection, threading connection, adhering or supersonic welding. Air outlet slot openings 14B are provided at both sides of the front end of the upper housing 12, which is combined with the air outlet slot openings 14A of the lower housing 11 to form the air outlets 14 of the housing 10. A plurality of tapped pillar 22 are provided at both sides of the top surface inside the upper housing 12. A pair of positioning ribs 23 is provided contiguously at the inner side of each tapped pillar 22.

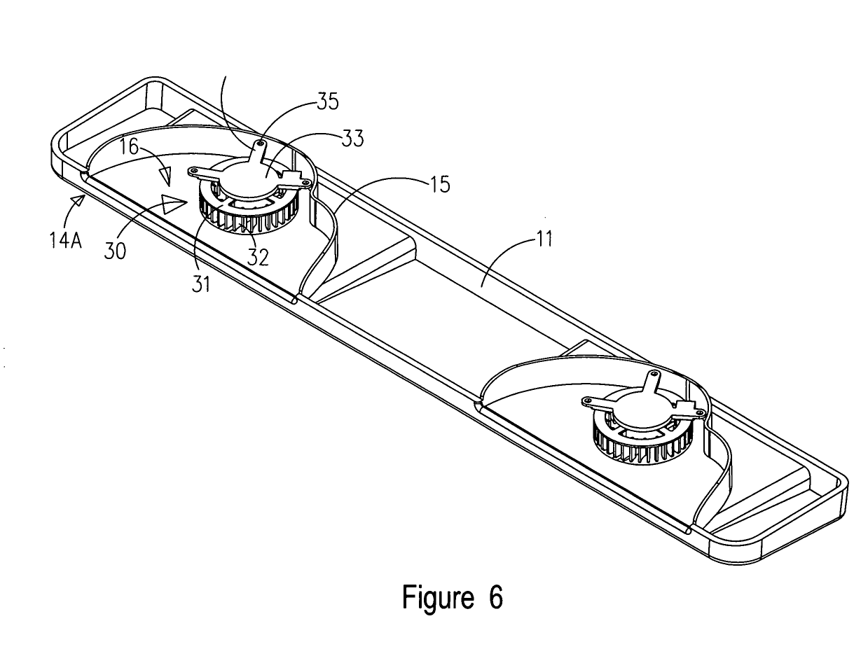

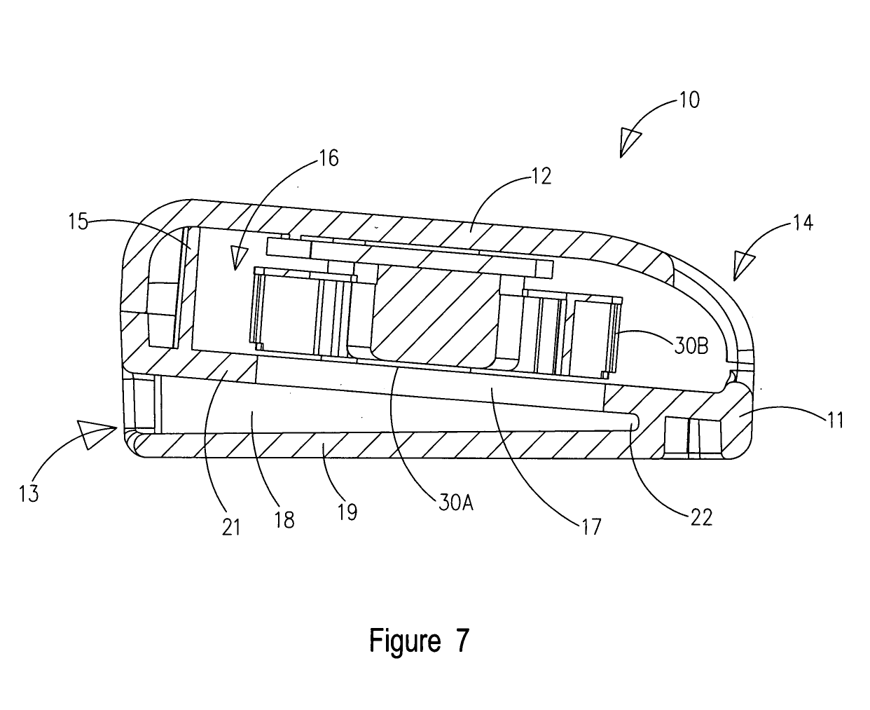

Referring to FIGS. 6 and 7, each side-blow fan 30 is provided at respective fan casing 16 of the housing 10, which includes a fan bracket 31 and a plurality of annularly arranged fan blades 32. One side of the fan bracket 31 has a fixing mount 33 which is provided with a plurality of fixing plates 34 extending in radial direction. A fixing hole 34 is provided on each fixing plate 34. In assembling, The fixing plate 34 is inserted and positioned into the positioning ribs 23 by the leaning of the fixing mount 33 against the internal top surface of the upper housing 12, and the side-blow fan 30 is fixed onto the upper housing 12 by the thread engagement of a screw (not shown) into the fixing hole 34 and the tapped pillar 22. The other side opposite to the fixing mount 33 of the side-blow fan 30 is formed as a air suction face 30A, and the surface annularly arranged with a plurality of fan blades 32 is formed as an air discharge face 30B. The air suction face 30A is corresponding to the air suction opening 17, while the air discharge face 30B is corresponding to the wind enclosing wall 15 and the air outlet 14.

In the application of the heat dissipation device for portable computer of the present invention, a portable computer is firstly disposed on the housing 10, then the side-blow fans 30 is started. The outside cold air enters the air ducts 18 after passing through the air inlets 13, and then is sucked by the side-blow fan 30 after passing through the air suction opening 17. Then the air enters into the fan casings 16 and is blown out from the air outlets 14 provided at the front end of the housing 10 to conduct the heat dissipation action for the base of the portable computer. The specialized design of the air ducts 18 and the unblocking of the air inlets 13 of the present invention allows the air speed within the air ducts 18 and the fan casings 16 become faster (larger air intake) and is quieter than before, so that excellent heat dissipation effect and practicality is achieved.

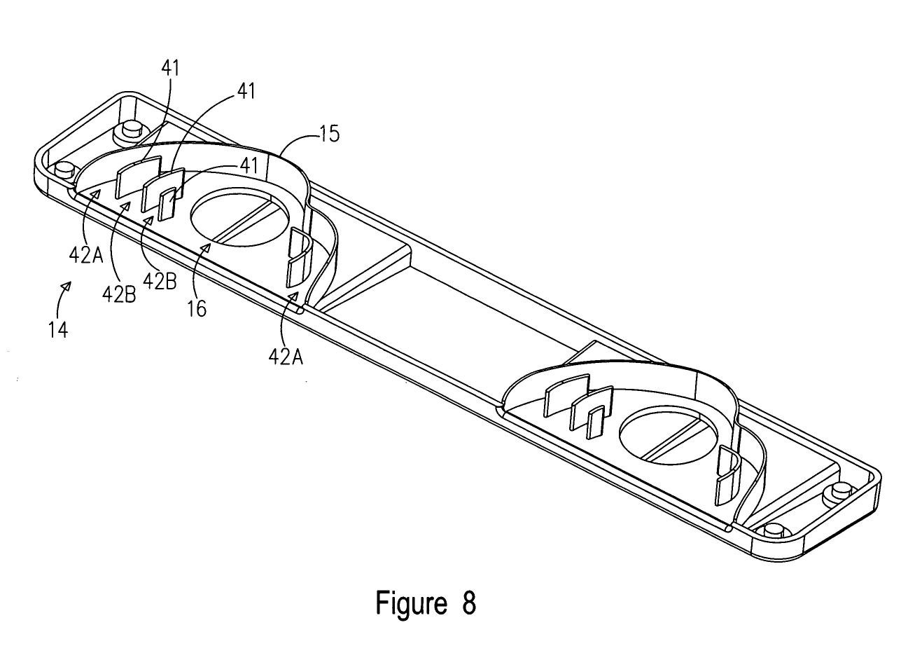

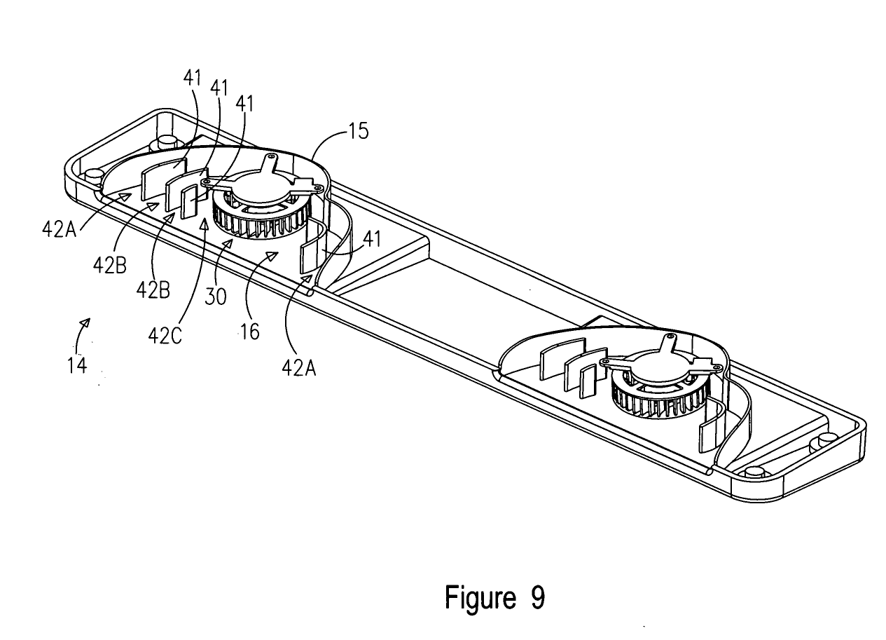

Further referring to FIGS. 8 and 9, a plurality of guide vane plates 41 are further provided within each fan casing 16 of the lower housing 11, which are distributed at both sides of the fan casings 16. An outer guide vane channel 42A is formed between the guide vane plate 41 and the wind enclosing wall 15, a guide vane channel 42B is formed between two guide vane plates 41, and an inner guide vane plate 42C is formed between the guide vane plate 41 and the side-blow fan 30. Appropriate uniform flow-dividing and guiding action can be achieved by the outer guide vane channel 42A, the guide vane channel 42B and the inner guide vane plate 42C, such that the air blown out by the side-blow fan 30 can be blown out rapidly and smoothly so as to obtain better cooling effect.

Summing up above, the present invention is in conformity with the requirement for a patent, and a patent application is hereby submitted. It is also noted that the abovementioned preferred embodiment is purely for the convenience of description only, not intended to be restrictive on the scope of the present invention. Any modifications and variations or the equivalents developed without departing from the spirit and principle of the present invention is considered to be still within the scope of the present invention.

What is claimed is:

1. A heat dissipation device for portable computer, comprising
a housing including at least one fan casing and duct in the interior, said fan casing having an air suction opening which communicates with said duct, at least one air outlet communicating with said fan casing being provided at the front end of said housing, at least one air inlet communicating with said fan casing being provided at the rear end of said housing; and
at least one side-blow fan provided within the fan casing, the air suction face of said side-blow fan being opposite to the air suction opening so that the air introducing from the air inlet into the duct is sucked by the side-blow fan into the fan casing after passing through the air suction opening and blowing out forward through said air outlet.

2. A heat dissipation device for portable computer as claimed in claim 1, wherein said housing further comprises
a lower housing, and
an upper housing provided and fixed on said lower housing.

3. A heat dissipation device for portable computer as claimed in claim 2, wherein said lower housing contains said fan casing, said air duct, said air inlet and said air outlet, said air duct being located below said fan casing, said air inlet being located at the rear side of said lower housing, said air outlet being located at the front side of said lower housing.

4. A heat dissipation device for portable computer as claimed in claim 2, wherein said upper housing contains said air inlet and said air outlet, said air inlet being located at the rear side of said upper housing, said air outlet being located at the front side of said upper housing . . . .

5. A heat dissipation device for portable computer as claimed in claim 1, wherein said air duct is formed by the bottom wall and the inner wall of said housing, and said air duct is located at the bottom of said housing.

6. A heat dissipation device for portable computer as claimed in claim 1, wherein the interior of said housing further comprises at least one wind enclosing wall for forming said fan casing, said wind enclosing wall is relatively located at the rear end of said air outlet.

7. A heat dissipation device for portable computer as claimed in claim 1, further comprising:
at least one fixing mount provided on said side-blow fan for fixing said side-blow fan onto said housing.

8. A heat dissipation device for portable computer as claimed in claim 1, further comprising at least one power supply/signal transmission port electrically connected with said side-blow fan.

9. A heat dissipation device for portable computer as claimed in claim 1, wherein said air duct is an inclined air duct tapering from the rear side to the front side.

10. A heat dissipation device for portable computer as claimed in claim 5, wherein the front end of said air duct is a closed end, and a support partitioning plate is further provided within the air duct for supporting the inner wall of said housing.

11. A heat dissipation device for portable computer as claimed in claim 1, wherein at least one guide vane plate for producing a flow guiding channel is provided within said fan casing.
